(19) United States
(12) Patent Application Publication
(10) Pub. No.: US 2024/0213346 A1
(43) Pub. Date: Jun. 27, 2024

(54) SEMICONDUCTOR DEVICE AND METHOD OF MANUFACTURING SEMICONDUCTOR DEVICE

(71) Applicant: SUMITOMO ELECTRIC DEVICE INNOVATIONS, INC., Kanagawa (JP)

(72) Inventor: Hiroaki KATO, Kanagawa (JP)

(21) Appl. No.: 18/545,249

(22) Filed: Dec. 19, 2023

(30) Foreign Application Priority Data
Dec. 26, 2022 (JP) 2022-208885

(51) Int. Cl. H01L 29/45; H01L 21/768; H01L 23/48; H01L 29/20; H01L 29/40; H01L 29/66; H01L 29/778

(52) U.S. Cl. CPC H01L 29/452; H01L 21/76898; H01L 23/481; H01L 29/2003; H01L 29/401; H01L 29/66462; H01L 29/7786

(57) ABSTRACT

A semiconductor device includes a substrate having a first surface and a second surface opposite to the first surface; a first nitride semiconductor layer having a third surface that is in contact with the second surface and a fourth surface opposite to the third surface, a recess being formed in the fourth surface; a second nitride semiconductor layer provided in the recess; and a first metal layer provided on the second nitride semiconductor layer. A through-hole is formed to penetrate the substrate, the first nitride semiconductor layer, and the second nitride semiconductor layers and expose the first metal layer. The semiconductor device further includes a second metal layer that is in contact with the first metal layer and that covers the first surface and an inner wall surface of the through-hole. The second nitride semiconductor layer contains impurity atoms at a concentration of 1.0×10¹⁸ cm⁻³ or greater.

### CROSS-REFERENCE TO RELATED APPLICATIONS

This application claims priority to Japanese Patent Application No. 2022-208885, filed on Dec. 26, 2022, the entire subject matter of which is incorporated herein by reference.

### TECHNICAL FIELD

The present disclosure relates to a semiconductor device and a method of manufacturing the semiconductor device.

### BACKGROUND

A semiconductor device, in which a semiconductor layer is formed on a substrate, a metal layer is formed on the semiconductor layer as an etching stopper, a through-hole reaching the etching stopper is formed in the substrate and the semiconductor layer, and a back surface electrode connected to the etching stopper through the through-hole is formed on a lower surface of the substrate, is known.

[Patent Document 1] Japanese Laid-Open Patent Application Publication No. 2019-145546

[Patent Document 2] Japanese Laid-Open Patent Application Publication No. 2020-17647

### SUMMARY

According to an embodiment of the present disclosure, a semiconductor device includes a substrate having a first surface and a second surface opposite to the first surface; a first nitride semiconductor layer having a third surface that is in contact with the second surface and a fourth surface opposite to the third surface, a recess being formed in the fourth surface; a second nitride semiconductor layer provided in the recess; and a first metal layer provided on the second nitride semiconductor layer. A through-hole is formed in the substrate, the first nitride semiconductor layer, and the second nitride semiconductor layer, the through-hole penetrating the substrate, the first nitride semiconductor layer, and the second nitride semiconductor layer and exposing the first metal layer. The semiconductor device further includes a second metal layer that is in contact with the first metal layer and that covers the first surface and an inner wall surface of the through-hole. The second nitride semiconductor layer contains impurity atoms at a concentration of 1.0×10¹⁸ cm⁻³ or greater.

### BRIEF DESCRIPTION OF THE DRAWINGS

FIG. 1 is a diagram illustrating a layout of a gate electrode, a source wiring, and a drain wiring in a semiconductor device according to an embodiment;

FIG. 2 is a cross-sectional view illustrating the semiconductor device according to the embodiment;

FIG. 3 is a diagram illustrating a band structure of a semiconductor layer (a regrown layer);

FIG. 4 is a diagram illustrating a layout of a gate electrode, a source wiring, and a drain wiring in a semiconductor device according to a reference example;

FIG. 5 is a cross-sectional view illustrating the semiconductor device according to the reference example;

FIG. 6 is a cross-sectional view (1) illustrating a first example of a method of manufacturing the semiconductor device according to the embodiment;

FIG. 7 is a cross-sectional view (2) illustrating the first example of the method for manufacturing the semiconductor device according to the embodiment;

FIG. 8 is a cross-sectional view (3) illustrating the first example of the method of manufacturing the semiconductor device according to the embodiment;

FIG. 9 is a cross-sectional view (4) illustrating the first example of the method for manufacturing the semiconductor device according to the embodiment;

FIG. 10 is a cross-sectional view (5) illustrating the first example of the method for manufacturing the semiconductor device according to the embodiment;

FIG. 11 is a cross-sectional view (6) illustrating the first example of the method of manufacturing the semiconductor device according to the embodiment;

FIG. 12 is a cross-sectional view (7) illustrating the first example of the method of manufacturing the semiconductor device according to the embodiment;

FIG. 13 is a cross-sectional view (8) illustrating the first example of the method for manufacturing the semiconductor device according to the embodiment;

FIG. 14 is a cross-sectional view (9) illustrating the first example of the method for manufacturing the semiconductor device according to the embodiment;

FIG. 15 is a cross-sectional view (1) illustrating a second example of the method of manufacturing the semiconductor device according to the embodiment; and

FIG. 16 is a cross-sectional view (2) illustrating the second example of the method of manufacturing the semiconductor device according to the embodiment.

### DETAILED DESCRIPTION

### [Problem to be Solved by the Present Disclosure]

In a semiconductor device in the related art, a metal layer for ensuring the ohmic contact is provided because a metal layer formed as an etching stopper cannot be brought into ohmic contact with a semiconductor layer. Thus, as the number of through-holes increases, it becomes more difficult to reduce the size of the semiconductor device.

### [Effect of the Present Disclosure]

According to the present disclosure, the size of the semiconductor device can be reduced.

### [Description of Embodiments of the Present Disclosure]

First, embodiments of the present disclosure will be listed and described.

[1] A semiconductor device according to one aspect of the present disclosure includes a substrate having a first surface and a second surface opposite to the first surface; a first nitride semiconductor layer having a third surface that is in contact with the second surface and a fourth surface opposite to the third surface, a recess being formed in the fourth surface; a second nitride semiconductor layer provided in the recess; and a first metal layer provided on the second nitride semiconductor layer. A through-hole is formed in the substrate, the first nitride semiconductor layer, and the second nitride semiconductor layer, the through-hole penetrating the substrate, the first nitride semiconductor layer, and the second nitride semiconductor layer and exposing the first metal layer. The semiconductor device further includes a second metal layer that is in contact with the first metal layer and that covers the first surface and an inner wall surface of the through-hole. The second nitride semiconductor layer contains impurity atoms at a concentration of 1.0×10¹⁸ cm⁻³ or greater.

The second nitride semiconductor layer is formed in the recess formed in the fourth surface of the first nitride semiconductor layer, and the second nitride semiconductor layer contains the impurity atoms at the concentration of 1.0×10¹⁸ cm⁻³ or greater. Thus, the ohmic contact is obtained between the second nitride semiconductor layer and the first metal layer, and a range of selection of the material of the first metal layer can be increased. Even when a metal having low reactivity with the second metal layer is used as the first metal layer, the ohmic contact with the second nitride semiconductor layer can be obtained. That is, due to the first metal layer, the ohmic contact with the second nitride semiconductor layer and the metallic bonding with the second metal layer with a low electrical resistance can be obtained. Therefore, the size can be reduced in comparison with a case where a metal layer for the ohmic contact and a metal layer for the metallic bonding with the second metal layer with a low electrical resistance are used.

[2] In [1], the second nitride semiconductor layer may be a gallium nitride layer. In this case, a low electrical resistance is easily obtained in the second nitride semiconductor layer.

[3] In [1] or [2], the first metal layer may include a nickel layer that is in contact with the second nitride semiconductor layer and that is exposed in the through-hole, and the second metal layer may include a gold layer that is in contact with the nickel layer. In this case, due to the gold layer, a low electrical resistance is obtained in the second metal layer. Additionally, because the nickel layer and the gold layer do not easily react with each other, an alloy layer is not easily formed at the interface therebetween, and an increase in the electrical resistance due to the formation of the alloy layer can be suppressed.

[4] In any one of [1] to [3], in the second nitride semiconductor layer, a Fermi level may be higher than energy of a lower end of a conduction band. In this case, the ohmic contact is easily obtained between the second nitride semiconductor layer and the first metal layer.

[5] A carrier density in the second nitride semiconductor layer may be higher than a carrier density in the first nitride semiconductor layer. In this case, the electrical resistance of the second nitride semiconductor layer is easily reduced.

A method of manufacturing a semiconductor device according to another aspect of the present disclosure includes forming a first nitride semiconductor layer on a substrate having a first surface and a second surface opposite to the first surface, the first nitride semiconductor layer having a third surface that is in contact with the second surface and a fourth surface opposite to the third surface; forming a recess in the fourth surface; forming a second nitride semiconductor layer in the recess; forming a first metal layer on the second nitride semiconductor layer; forming a through-hole in the substrate, the first nitride semiconductor layer, and the second nitride semiconductor layer, the through-hole penetrating the substrate, the first nitride semiconductor layer, and the second nitride semiconductor layer and exposing the first metal layer; and forming a second metal layer that is in contact with the first metal layer and covers the first surface and an inner wall surface of the through-hole. The second nitride semiconductor layer contains impurity atoms at a concentration of 1.0×10¹⁸ cm⁻³ or greater.

The recess is formed in the fourth surface of the first nitride semiconductor layer, the second nitride semiconductor layer is formed in the recess, and the second nitride semiconductor layer contains the impurity atoms at the concentration of 1.0×10¹⁸ cm⁻³ or greater. Thus, the ohmic contact is obtained between the second nitride semiconductor layer and the first metal layer, and a range of selection of the material of the first metal layer is increased. Therefore, the size can be reduced in comparison with a case where a metal layer for the ohmic contact and a metal layer for the metallic bonding with the second metal layer with a low electrical resistance are used.

### [Details of Embodiments of the Present Disclosure]

In the following, embodiments of the present disclosure will be described in detail, but the present disclosure is not limited thereto. Here, in the present specification and the drawings, components having substantially the same functional configurations are denoted by the same reference symbols, and duplicated description thereof may be omitted. Additionally, in the following description, an XYZ orthogonal coordinate system is used. However, the coordinate system is defined for description and does not limit the posture of the semiconductor device. Additionally, when viewed from an arbitrary point, the +Z side may be referred to as above, an upper side, or up, and the −Z side may be referred to as below, a lower side, or down.

### (Configuration of Semiconductor Device)

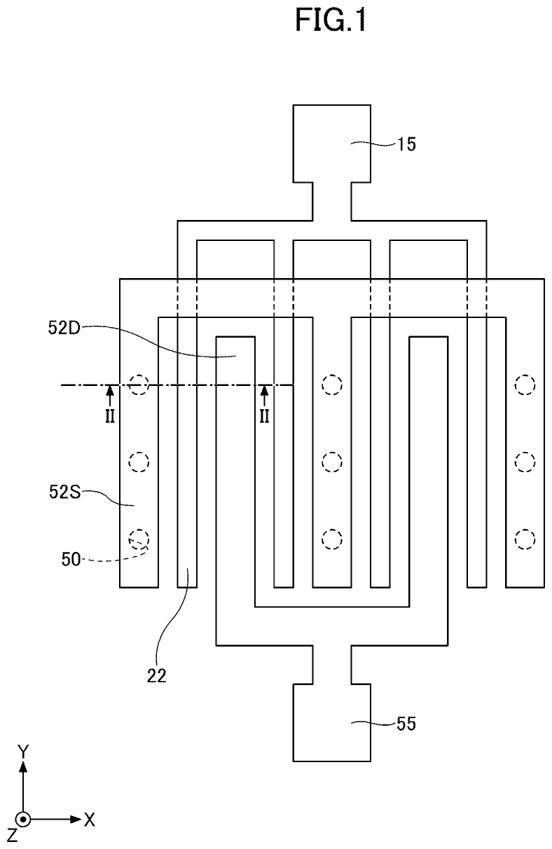

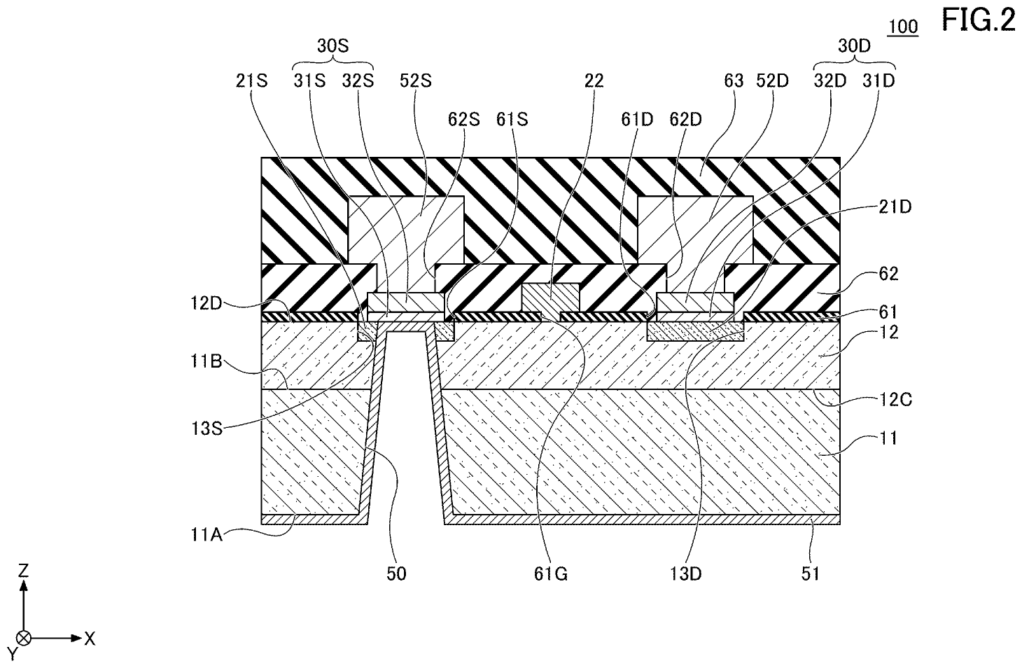

The embodiments relate to a semiconductor device including a GaN-based high electron mobility transistor (HEMT). FIG. 1 is a diagram illustrating a layout of a gate electrode, a source wiring, and a drain wiring in a semiconductor device according to an embodiment. FIG. 2 is a cross-sectional view illustrating the semiconductor device according to the embodiment. FIG. 2 corresponds to a cross-sectional view taken along the line II-II in FIG. 1.

As illustrated in FIG. 1 and FIG. 2, a semiconductor device 100 according to the embodiment mainly includes a substrate 11, a semiconductor layer 12, a semiconductor layer 21S, a semiconductor layer 21D, a gate electrode 22, a source electrode 30S, a drain electrode 30D, a source wiring 52S, a drain wiring 52D, and a back surface electrode 51.

The substrate 11 is, for example, a silicon carbide (SiC) substrate. The substrate 11 has a first surface 11A and a second surface 11B opposite to the first surface 11A. The second surface 11B is positioned above the first surface 11A (on the +Z side).

The semiconductor layer 12 is provided on the substrate 11. The semiconductor layer 12 has a third surface 12C that is in contact with the second surface 11B and a fourth surface 12D that is opposite to the third surface 12C. The fourth surface 12D is above the third surface 12C (on +Z side). The semiconductor layer 12 is, for example, a nitride semiconductor layer containing gallium (Ga). The nitride semiconductor layer forms a part of a high electron mobility transistor, such as an electron transit layer (a channel layer) and an electron supply layer (a barrier layer). The semiconductor layer 12 is an example of a first nitride semiconductor layer.

Multiple recesses 13S and multiple recesses 13D are formed in the fourth surface 12D. The recesses 13S and 13D extend parallel to the Y-axis direction and are alternately provided in the X-axis direction. For example, the recesses 13S and 13D reach the electron transit layer (the channel layer). The bottom surfaces of the recesses 13S and 13D may be in the electron transit layer.

The semiconductor device 100 includes an insulating film 61. The insulating film 61 covers the fourth surface 12D of the semiconductor layer 12. For example, the insulating film 61 is a nitride film, such as a silicon nitride (SiN) film. Multiple openings 61S, multiple openings 61D, and multiple openings 61G are formed in the insulating film 61. The openings 61S, 61D, and 61G extend parallel to the Y-axis direction. The opening 61S is continuous with the recess 13S, and the opening 61D is continuous with the recess 13D. The opening 61G is provided between the opening 61S and the opening 61D adjacent to each other in the X-axis direction.

The semiconductor layer 21S is provided in the recess 13S, and the semiconductor layer 21D is provided in the recess 13D. A portion of the semiconductor layer 21S may be inside the opening 61S, and a portion of the semiconductor layer 21D may be inside the opening 61D. For example, the semiconductor layers 21S and 21D are gallium nitride (GaN) layers having an n-type conductivity. The semiconductor layers 21S and 21D are regrown layers. The carrier densities in the semiconductor layers 21S and 21D are higher than the carrier density in the semiconductor layer 12. The semiconductor layers 21S and 21D contain n-type impurity atoms at a concentration of 1.0×10¹⁸ cm⁻³ or greater. The semiconductor layers 21S and 21D are, for example, degenerate semiconductor layers. The n-type impurity is, for example, silicon (Si) or germanium (Ge). The semiconductor layer 21S is an example of a second semiconductor nitride layer.

The gate electrode 22 extends parallel to the Y-axis direction. The gate electrode 22 covers the opening 61G of the insulating film 61 and is in Schottky contact with the semiconductor layer 12 through the opening 61G. The gate electrode 22 includes, for example, a nickel (Ni) layer and a gold (Au) layer laminated in this order upward. As illustrated in FIG. 1, multiple gate electrodes 22 are connected to a gate common connection 15.

The source electrode 30S and the drain electrode 30D extend parallel to the Y-axis direction. The source electrode 30S includes an Ni layer 31S and an Au layer 32S inside the opening 61S in plan view. The Ni layer 31S is provided on the semiconductor layer 21S, and the Au layer 32S is provided on the Ni layer 31S. The Ni layer 31S is in direct contact with the semiconductor layer 21S. The drain electrode 30D includes an Ni layer 31D and an Au layer 32D inside the opening 61D in plan view. The Ni layer 31D is provided on the semiconductor layer 21D, and the Au layer 32D is provided on the Ni layer 31D. The Ni layer 31D is in direct contact with the semiconductor layer 21D. The source electrode 30S is an example of a first metal layer.

The semiconductor device 100 includes an insulating film 62. The insulating film 62 covers the source electrode 30S, the drain electrode 30D, the gate electrode 22, the insulating film 61, the semiconductor layer 21S, and the semiconductor layer 21D. For example, the insulating film 62 is a nitride film, such as a SiN film. Multiple openings 62S and multiple openings 62D are formed in the insulating film 62. The openings 62S and the 62D extend parallel to the Y-axis direction. The opening 62S reaches the source electrode 30S, and the opening 62D reaches the drain electrode 30D.

The source wiring 52S is located on and over the source electrode 30S. The source wiring 52S is provided on the insulating film 62. The source wiring 52S is in contact with the source electrode 30S through the opening 62S. The drain wiring 52D is located on and over the drain electrode 30D. The drain wiring 52D is provided on the insulating film 62. The drain wiring 52D is in contact with the drain electrode 30D through the opening 62D. The source wiring 52S and the drain wiring 52D each include, for example, a seed layer and a plating layer on the seed layer. For example, the seed layer includes a titanium (Ti) layer, and the plating layer includes an Au layer. As illustrated in FIG. 1, multiple drain wirings 52D may be connected to a drain pad 55, and multiple source wirings 52S may be connected to each other.

The semiconductor device 100 includes an insulating film 63. The insulating film 63 covers the source wiring 52S, the drain wiring 52D, and the insulating film 62. For example, the insulating film 63 is a nitride film, such as a SiN film.

Although not illustrated, an opening reaching the gate common connection 15 is formed in the insulating film 62, and a gate pad that is in contact with the gate common connection 15 through the opening is formed in the insulating film 62. Additionally, an opening reaching the gate pad and an opening reaching the drain pad 55 are formed in the insulating film 63.

A through-hole 50 penetrating the substrate 11, the semiconductor layer 12, and the semiconductor layer 21S is formed in the substrate 11, the semiconductor layer 12, and the semiconductor layer 21S. The through-hole 50 reaches the source electrode 30S. At least one through-hole 50 is formed for each of the source electrodes 30S. Multiple through-holes 50 may be formed for each of the source electrodes 30S.

The back surface electrode 51 is formed on a lower surface of the source electrode 30S, an inner wall surface of the through-hole 50, and a lower surface (a first surface 11A) of the substrate 11. The back surface electrode 51 is in contact with the source electrode 30S and covers the first surface 11A and the inner wall surface of the through-hole 50. For example, the back surface electrode 51 is formed of an Au layer. The back surface electrode 51 includes, for example, a seed layer and a plating layer. The back surface electrode 51 is an example of a second metal layer.

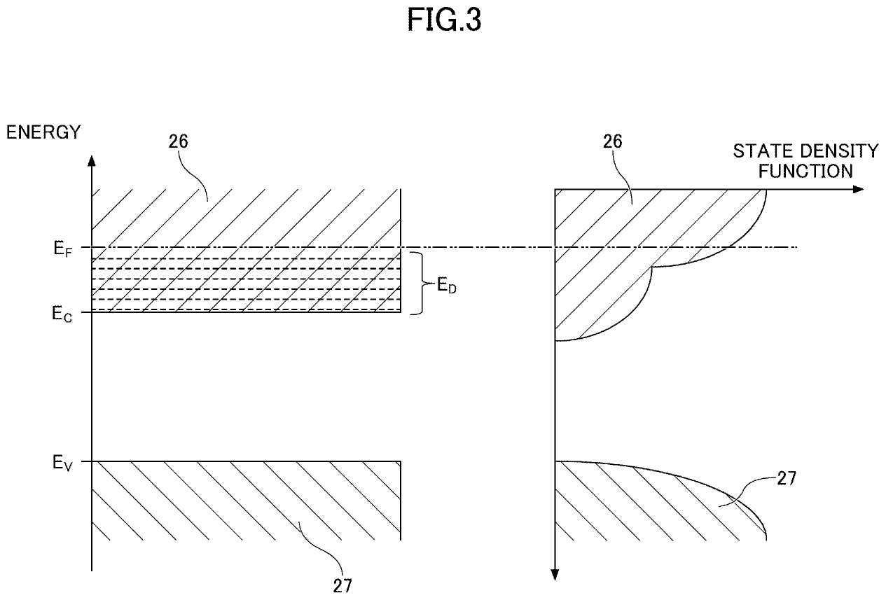

In the semiconductor device 100 according to the embodiment, the semiconductor layer 21S is formed in the recess 13S of the semiconductor layer 12, and the semiconductor layer 21S contains impurity atoms at a concentration of 1.0×10¹⁸ cm⁻³ or greater. In the semiconductor layer 21S, the distance between the impurity atoms is short, and as illustrated in FIG. 3, a binding band, in which the impurity levels (E_{D}) interact with each other, is formed, and the binding band is connected to a conduction band 26. At this time, the Fermi energy level (E_{F}) is present in the conduction band, that is, the Fermi energy level (E_{F}) is higher than the energy (E_{C}) at the bottom of the conduction band, so that the semiconductor layer 21S exhibits properties similar to the properties of metal. That is, the semiconductor layer 21S functions as a degenerate semiconductor layer. Therefore, the ohmic contact is obtained between the semiconductor layer 21S and the source electrode 30S. FIG. 3 is a diagram illustrating a band structure of the semiconductor layer 21S. Here, E_{V} in FIG. 3 represents the energy at an upper end of a valence band 27.

Because the semiconductor layer 21S exhibits the properties similar to the properties of metal, the range of selection for the material of the source electrode 30S is expanded. For example, as the material of the source electrode 30S, a material that is not easily alloyed with the material of the back surface electrode 51 can be used. More specifically, when the material of the back surface electrode 51 is Au, the source electrode 30S may include the Ni layer 31S that is in contact with the back surface electrode 51. The Ni layer 31S can be in ohmic contact with the semiconductor layer 21S, so that the ohmic contact with the semiconductor layer 21S and the metallic bonding with the back surface electrode 51 with a low electrical resistance can be obtained, due to the source electrode 30S. Thus, a stable potential can be supplied from the back surface electrode 51 to each of the source electrodes 30S. For example, a stable ground potential can be supplied from the back surface electrode 51 to each of the source electrodes 30S, thereby improving the gain and the operational reliability.

When the semiconductor layer 21S is a GaN layer, a low electrical resistance is easily obtained in the semiconductor layer 21S.

The source electrode 30S includes the Ni layer 31S and the back surface electrode 51 includes the Au layer, so that a low electrical resistance can be obtained in the back surface electrode 51 due to the Au layer, and an alloyed layer is not easily formed at the interface between the Ni layer 31S and the Au layer, thereby suppressing the increase in the electrical resistance along with the formation of the alloyed layer.

The carrier densities in the semiconductor layers 21S and 21D are higher than the carrier density in the semiconductor layer 12, so that the electrical resistance of the semiconductor device 100 is easily reduced. Specifically, the electrical resistance between the source wiring 52S and the drain wiring 52D is easily reduced.

The semiconductor layer 21S may contain n-type impurity atoms at a concentration of 1.0×10¹⁹ cm⁻³ or greater, or may contain n-type impurity atoms at a concentration of 1.0×10²⁰ cm⁻³ or greater. As the concentration of the n-type impurity atoms contained in the semiconductor layer 21S increases, the ohmic contact with the source electrode 30S is obtained more easily. Similarly, the semiconductor layer 21D may contain n-type impurity atoms at a concentration of 1.0×10¹⁹ cm⁻³ or greater, or may contain n-type impurity atoms at a concentration of 1.0×10²⁰ cm⁻³ or greater. As the concentration of the n-type impurity atoms contained in the semiconductor layer 21D increases, the ohmic contact with the drain electrode 30D is obtained more easily. The concentration of the impurity atoms can be measured by secondary ion mass spectrometry (SIMS).

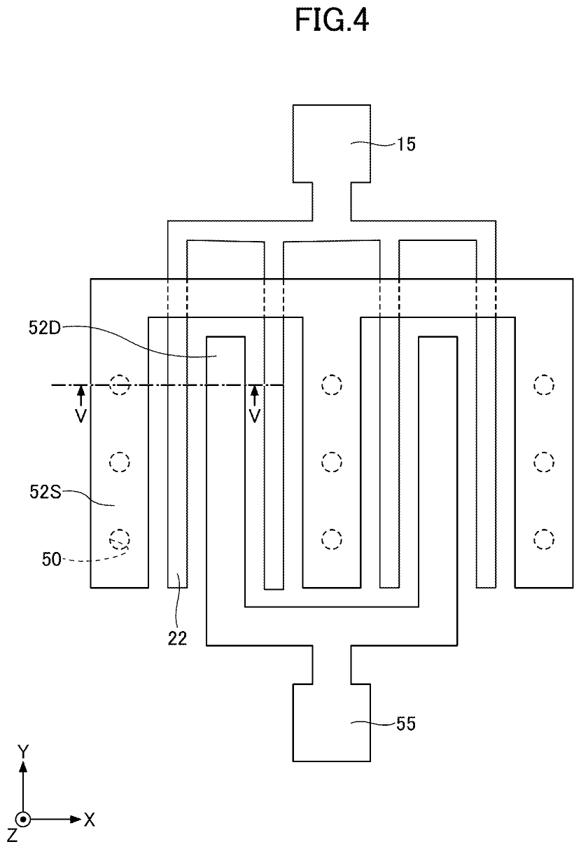

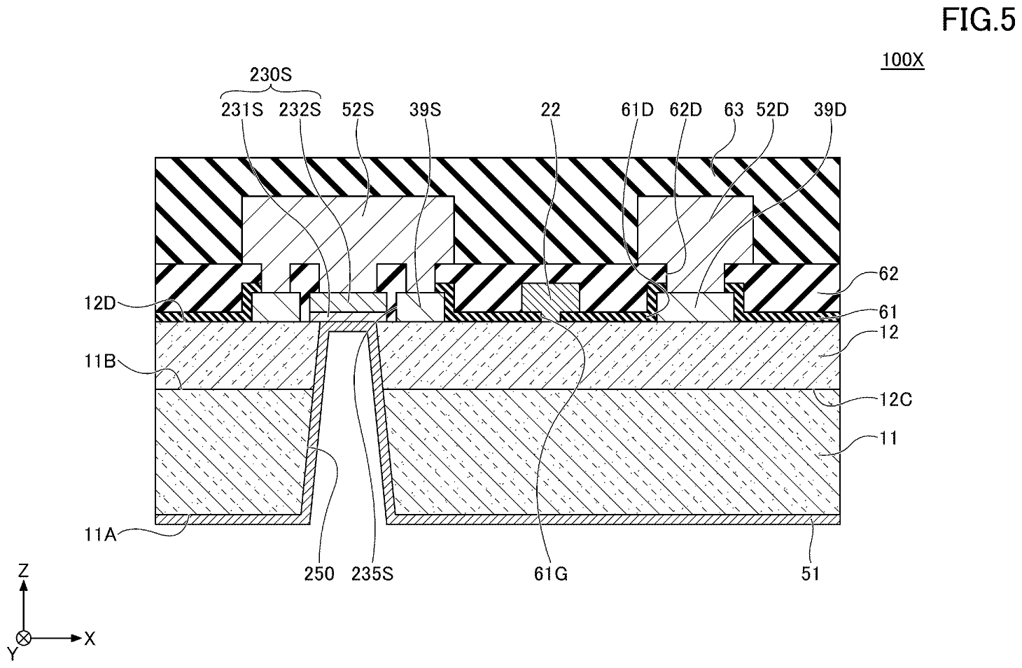

Here, the size-reduction, which is one of the effects of the embodiment, will be described in comparison with a reference example. FIG. 4 is a diagram illustrating a layout of a gate electrode, a source wiring, and a drain wiring in a semiconductor device according to the reference example. FIG. 5 is a cross-sectional view illustrating the semiconductor device according to the reference example. FIG. 5 corresponds to the cross-sectional view taken along the line V-V in FIG. 4.

As illustrated in FIG. 4 and FIG. 5, in a semiconductor device 100X according to the reference example, the recesses 13S and 13D are not formed in the semiconductor layer 12. A source electrode 39S is provided instead of the source electrode 30S, and a drain electrode 39D is provided instead of the drain electrode 30D. The source electrode 39S and the drain electrode 39D are aluminum (Al) electrodes. The Al electrode is in ohmic contact with the semiconductor layer 12. In the X-axis direction, the distance between the gate electrode 22 and the source electrode 39S is equal to the distance between the gate electrode 22 and the source electrode 30S in the embodiment.

An opening 235S is formed in the source electrode 39S. The semiconductor layer 12 is exposed from the opening 235S. An etching stopper 230S is formed inside the opening 235S in plan view. The etching stopper 230S is in contact with the fourth surface 12D. The etching stopper 230S includes an Ni layer 231S and an Au layer 232S. The source wiring 52S is in contact with the source electrode 39S and the etching stopper 230S. The source electrode 39S and the etching stopper 230S are electrically connected to each other through the source wiring 52S.

A through-hole 250 penetrating the substrate 11 and the semiconductor layer 12 is formed in the substrate 11 and the semiconductor layer 12. The through-hole 250 reaches the etching stopper 230S. Multiple through-holes 250 are formed in each of the etching stoppers 230S.

The back surface electrode 51 is formed on a lower surface of the etching stopper 230S, the inner wall surface of the through-hole 250, and the lower surface (the first surface 11A) of the substrate 11. The back surface electrode 51 is in contact with the etching stopper 230S and covers the first surface 11A and the inner wall surface of the through-hole 250.

The other configurations are the same as those of the embodiment.

In the reference example, the semiconductor layer 21S is not provided, and an Al electrode is provided as the source electrode 39S in order to obtain the ohmic contact with the semiconductor layer 12. Al is easily alloyed by reacting with Au, which is the material of the back surface electrode 51, and an alloy layer having a high electrical resistance is formed along with the alloying. Therefore, the through-hole 250 is formed to reach the etching stopper 230S provided apart from the source electrode 39S.

Thus, as illustrated in FIG. 4, the width (the size in the X-axis direction) of the source wiring 52S is greater than that in the embodiment. From the opposite viewpoint, according to the embodiment, the source wiring 52S can be made less than that in the reference example. Therefore, according to the embodiment, the size of the semiconductor device 100 can be reduced. This effect becomes more noticeable as the number of the through-holes 50 increases.

### (First Example of Method of Manufacturing Semiconductor Device)

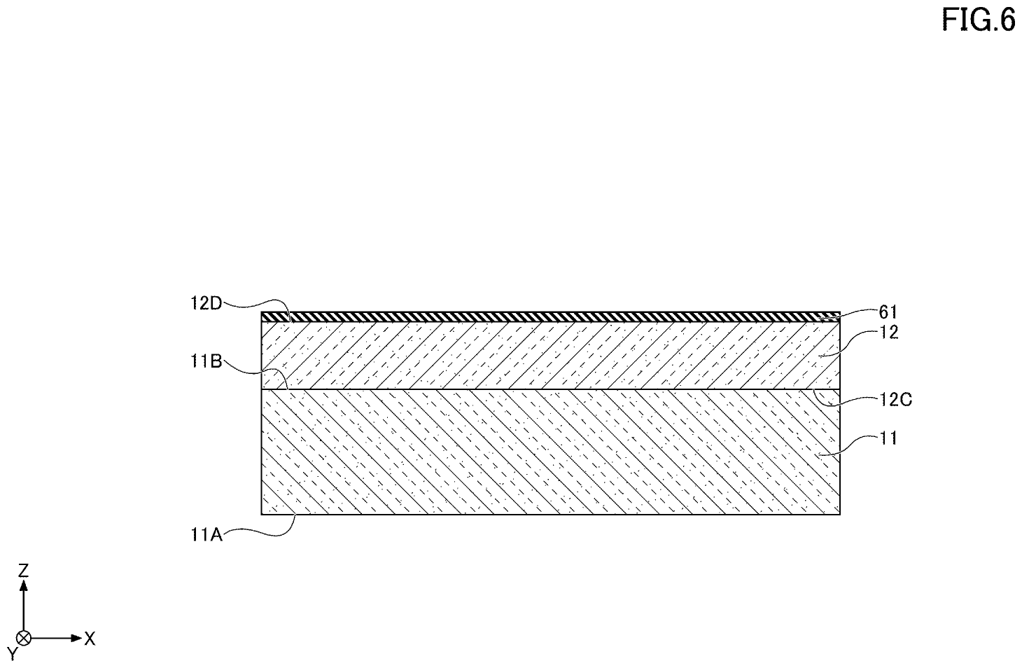

Next, a first example of a method of manufacturing the semiconductor device 100 according to the embodiment will be described. FIG. 6 to FIG. 14 are cross-sectional views illustrating the first example of the method of manufacturing the semiconductor device 100 according to the embodiment.

In the first example, first, as illustrated in FIG. 6, the semiconductor layer 12 is formed on the substrate 11 by, for example, a metal organic chemical vapor deposition (MOCVD) method. The substrate 11 has the first surface 11A and the second surface 11B opposite to the first surface 11A. The semiconductor layer 12 has a third surface 12C that is in contact with the second surface 11B, and the fourth surface 12D opposite to the third surface 12C. Next, the insulating film 61 is formed on the semiconductor layer 12. The insulating film 61 can be formed by, for example, a plasma CVD method. The insulating film 61 covers the fourth surface 12D of the semiconductor layer 12.

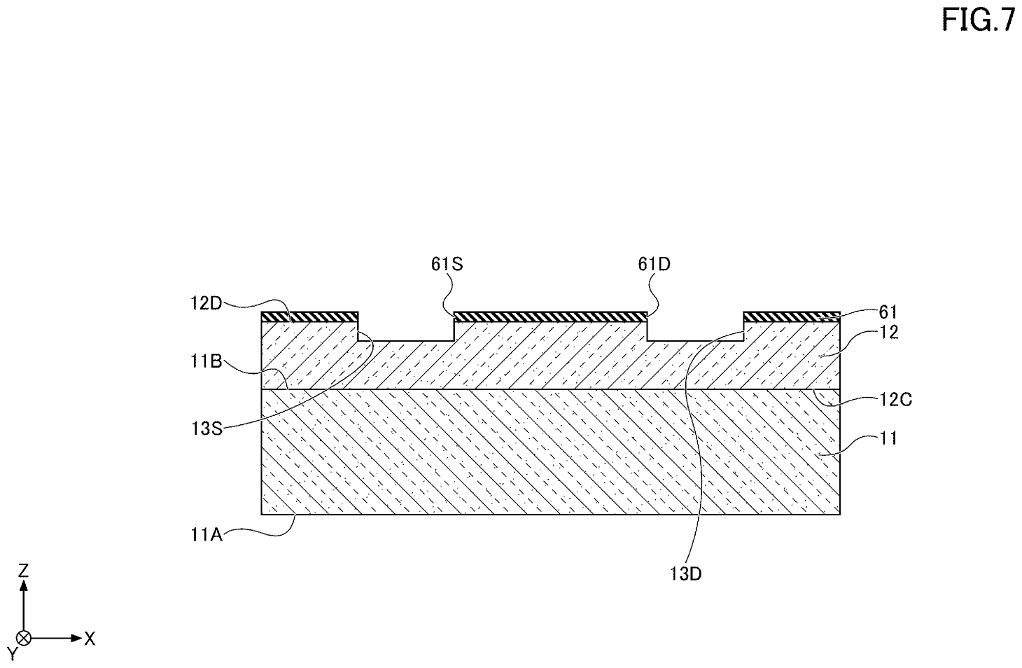

Next, as illustrated in FIG. 7, the openings 61S and 61D are formed in the insulating film 61, and the recesses 13S and 13D are formed in the semiconductor layer 12. In the formation of the openings 61S and 61D, for example, reactive ion etching (RIE) of the insulating film 61 is performed using a resist pattern as a mask. When the insulating film 61 is subjected to RIE, a reactive gas containing fluorine (F) is used, for example. In the formation of the recesses 13S and 13D, RIE of the semiconductor layer 12 is performed using the resist pattern used in the formation of the openings 61S and 61D as a mask. When the semiconductor layer 12 is subjected to RIE, a reactive gas containing chlorine (Cl) is used, for example.

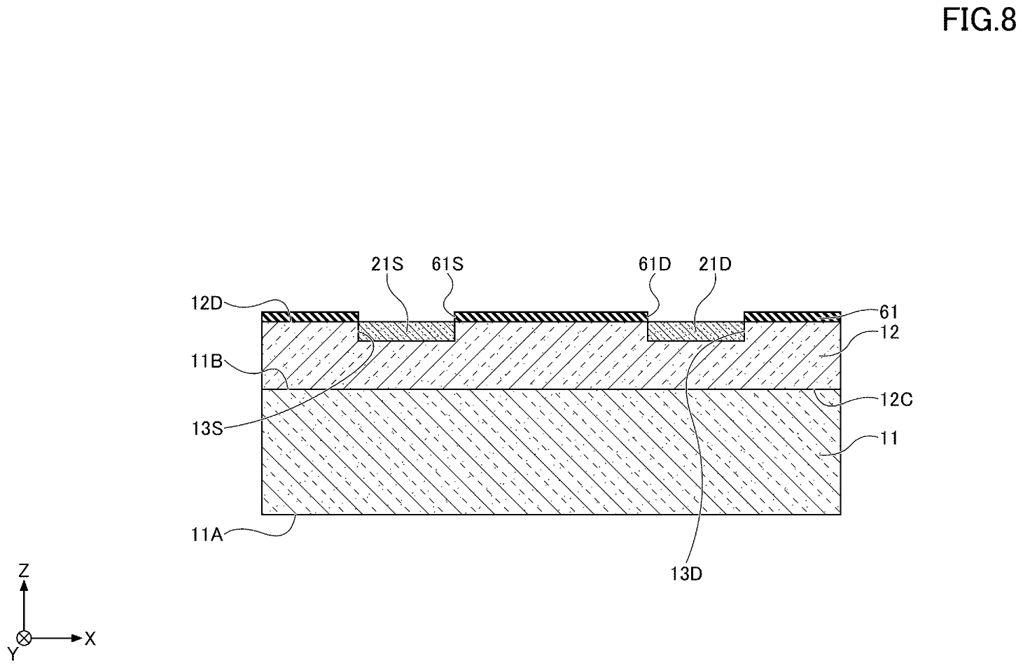

Next, as illustrated in FIG. 8, the semiconductor layer 21S is formed in the recess 13S, and the semiconductor layer 21D is formed in the recess 13D. In the formation of the semiconductor layers 21S and 21D, crystals of the semiconductor layer are grown by, for example, MOCVD, molecular beam epitaxy (MBE), or sputtering using a growth mask, and then removing the growth mask. The semiconductor layers 21S and 21D are what are called regrown layers.

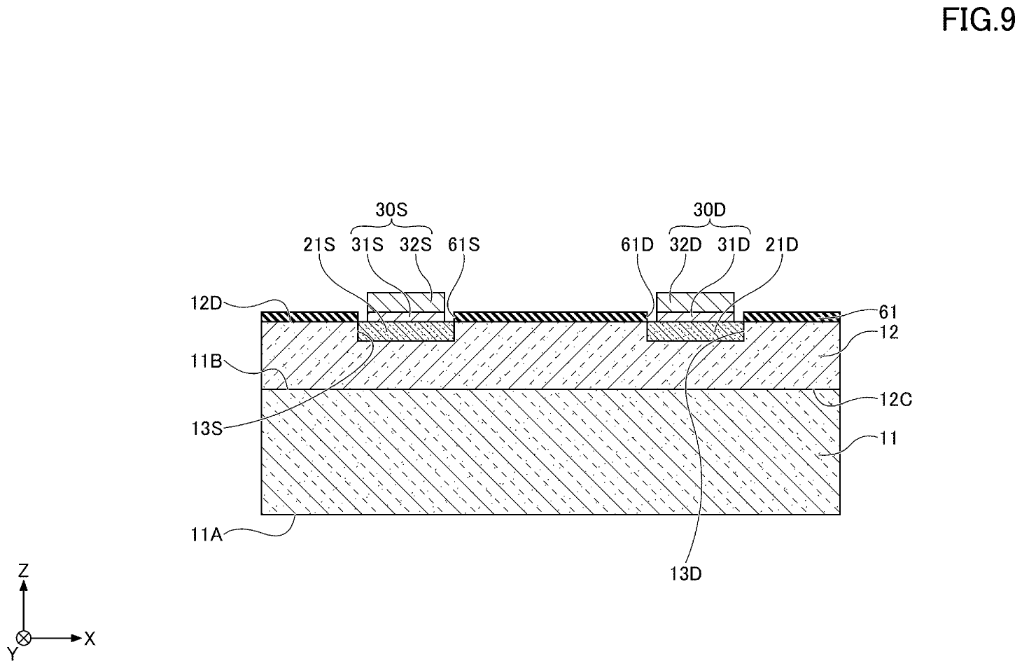

Next, as illustrated in FIG. 9, the source electrode 30S is formed on the semiconductor layer 21S, and the drain electrode 30D is formed on the semiconductor layer 21D. In the formation of the source electrode 30S and the drain electrode 30D, the Ni and Au layers are grown by vapor deposition using a growth mask, and then the growth mask is removed. That is, the source electrode 30S and the drain electrode 30D can be formed by, for example, vapor deposition and lift-off.

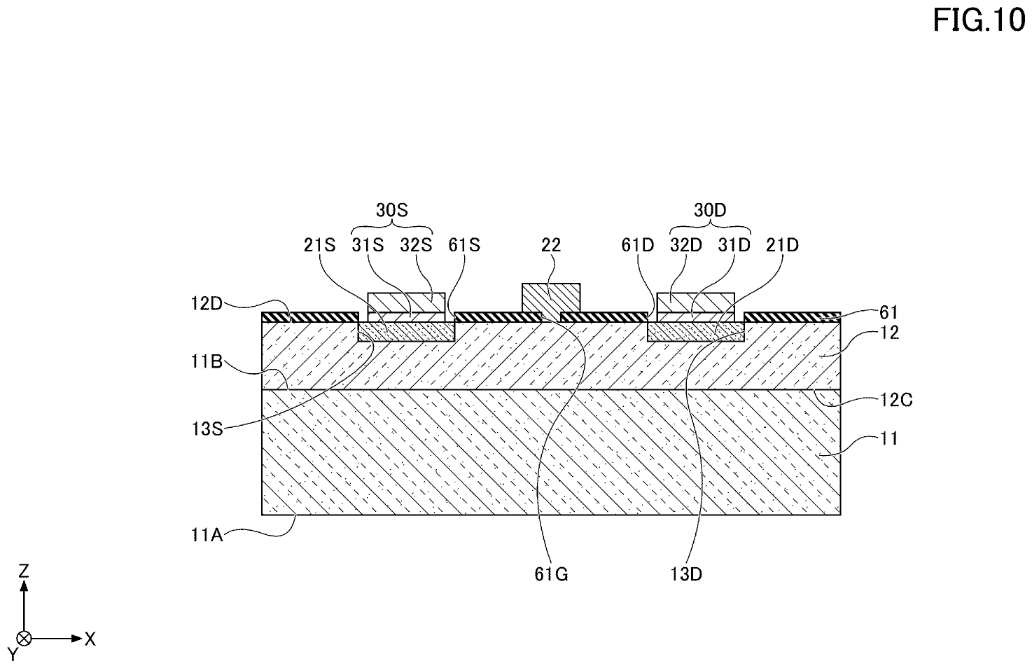

Next, as illustrated in FIG. 10, the opening 61G is formed in the insulating film 61. In the formation of the opening 61G, for example, RIE using a resist pattern as a mask is performed. A reactive gas containing F is used for etching the insulating film 61, for example. Next, the gate electrode 22 is formed on the insulating film 61. In the formation of the gate electrode 22, an Ni layer and an Au layer are grown by a vapor deposition method using a growth mask, and then the growth mask is removed. That is, the gate electrode 22 can be formed by, for example, vapor deposition and lift-off. The gate electrode 22 is in Schottky contact with the semiconductor layer 12 through the opening 61G.

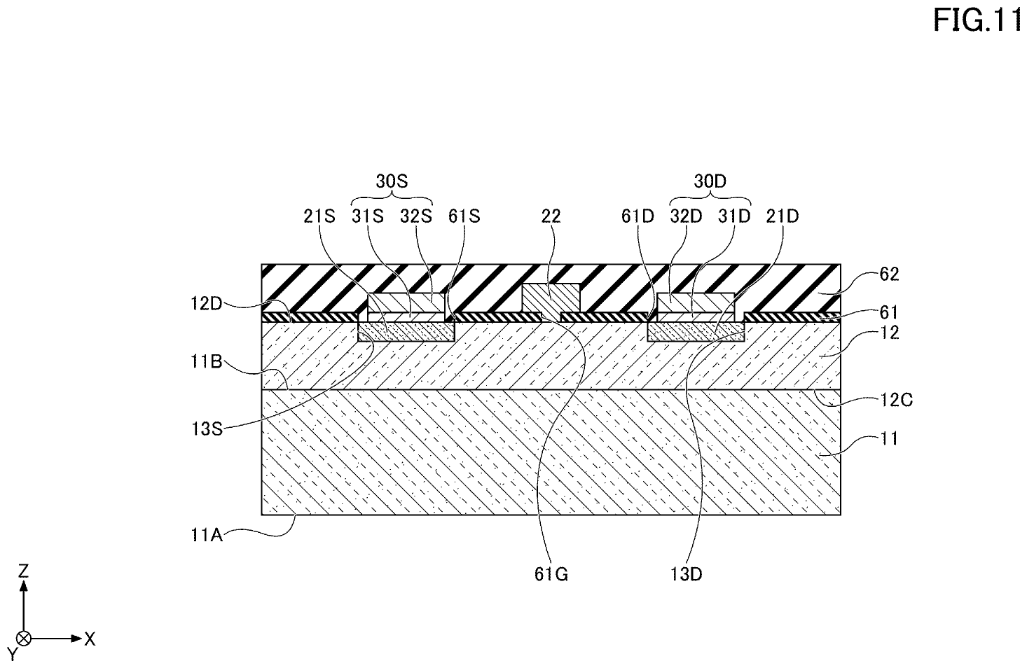

Next, as illustrated in FIG. 11, the insulating film 62 is formed on the insulating film 61. The insulating film 62 can be formed by, for example, a plasma CVD method. The insulating film 62 covers the source electrode 30S, the drain electrode 30D, the gate electrode 22, the insulating film 61, the semiconductor layer 21S, and the semiconductor layer 21D.

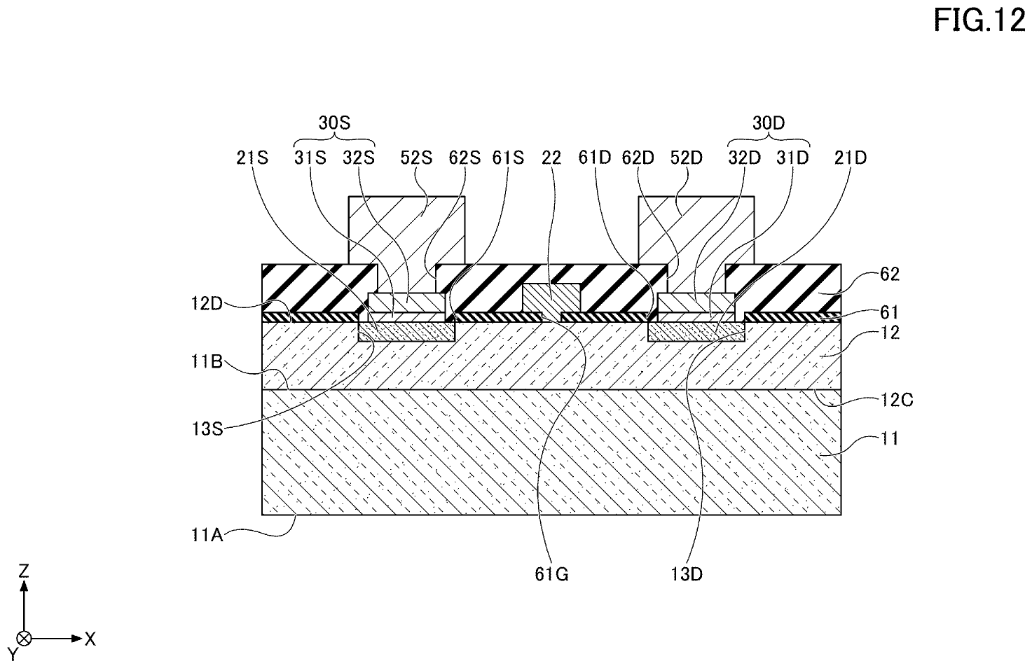

Next, as illustrated in FIG. 12, the openings 62S and 62D are formed in the insulating film 62. In the formation of the openings 62S and 62D, RIE of the insulating film 62 using a resist pattern as a mask is performed, for example. When the insulating film 62 is subjected to RIE, a reactive gas containing F is used, for example. Next, the source wiring 52S that is in contact with the source electrode 30S through the opening 62S and the drain wiring 52D that is in contact with the drain electrode 30D through the opening 62D are formed in the insulating film 62.

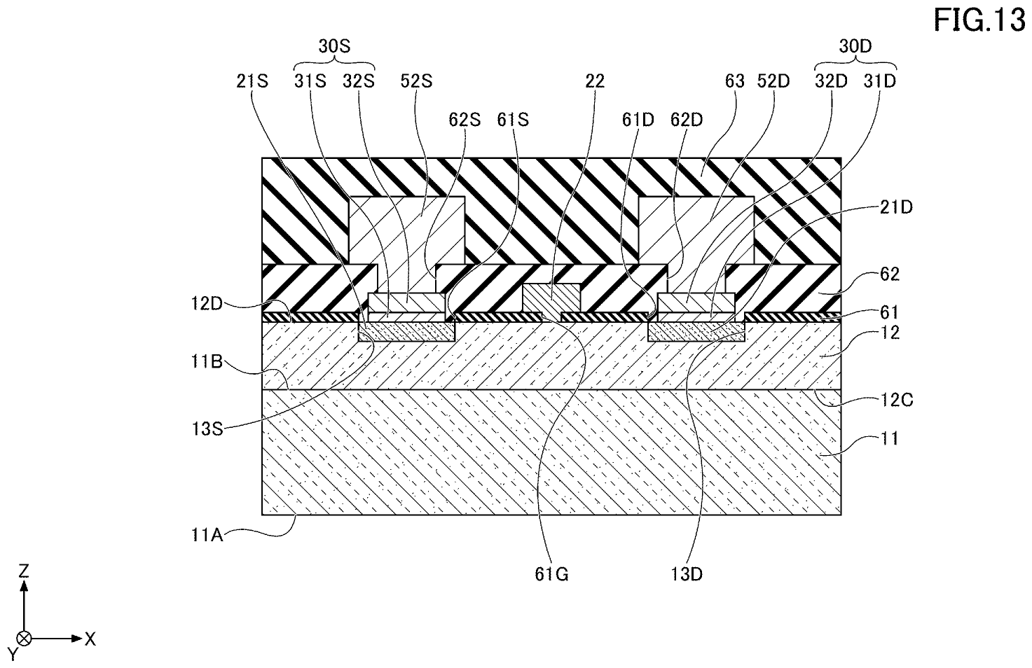

Next, as illustrated in FIG. 13, the insulating film 63 is formed on the insulating film 62. The insulating film 63 can be formed by, for example, a plasma CVD method. The insulating film 63 covers the source wiring 52S, the drain wiring 52D, and the insulating film 62.

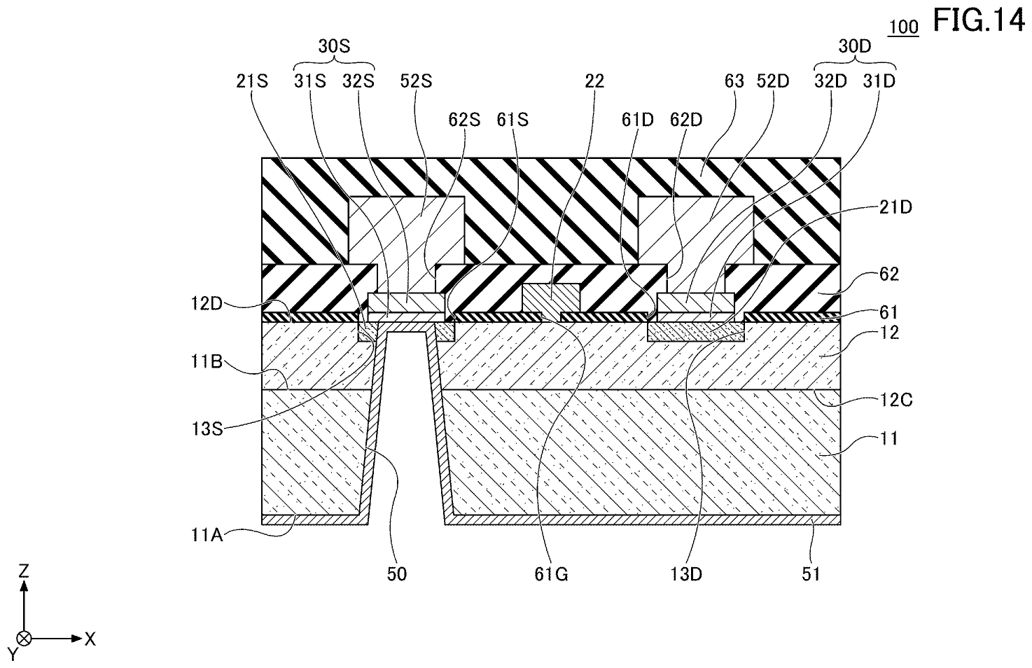

Next, as illustrated in FIG. 14, the through-hole 50 penetrating the substrate 11, the semiconductor layer 12, and the semiconductor layer 21S is formed in the substrate 11, the semiconductor layer 12, and the semiconductor layer 21S. The through-hole 50 is formed to reach the source electrode 30S. The lower surface of the source electrode 30S is exposed in the through-hole 50. In the formation of the through-hole 50, the etching of the semiconductor layer 12 is performed after the etching of the substrate 11 is performed. When the semiconductor layer 12 is etched, a reactive gas containing F is used, for example. The Ni layer 31S included in the source electrode 30S has high resistance to the etching using the reactive gas containing F. Therefore, the Ni layer 31S functions as the etching stopper. After the formation of the through-hole 50, the back surface electrode 51 is formed. The back surface electrode 51 is in contact with the source electrode 30S and covers the first surface 11A and the inner wall surface of the through-hole 50.

As described above, the semiconductor device 100 according to the first embodiment can be manufactured.

### (Second Example of Method of Manufacturing Semiconductor Device)

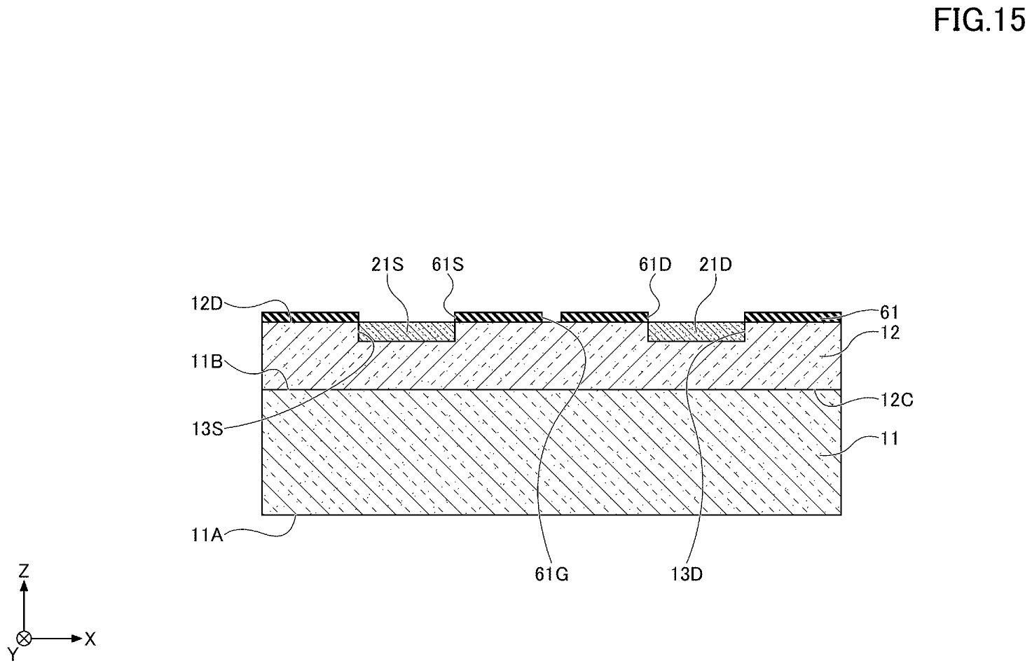

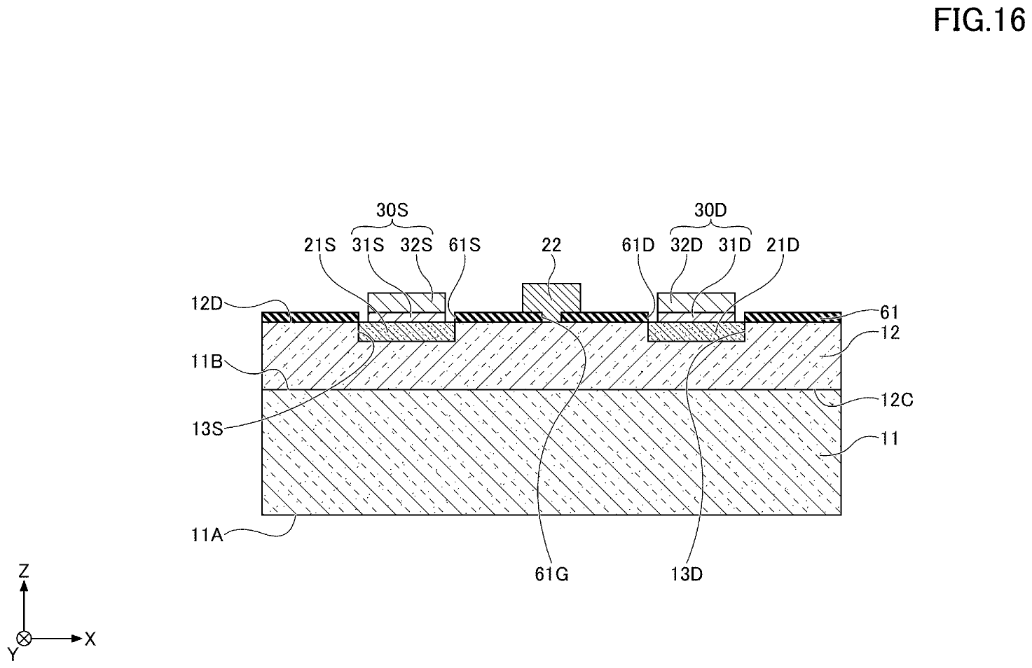

Next, a second example of the method for manufacturing the semiconductor device 100 according to the embodiment will be described. FIG. 15 and FIG. 16 are cross-sectional views illustrating the second example of the method of manufacturing the semiconductor device 100 according to the embodiment.

In the second example, first, the processes up to the formation of the semiconductor layers 21S and 21D are performed in the same procedure as that of the first example (see FIG. 6 to FIG. 8). Next, as illustrated in FIG. 15, the opening 61G is formed in the insulating film 61.

Next, as illustrated in FIG. 16, the source electrode 30S is formed on the semiconductor layer 21S, the drain electrode 30D is formed on the semiconductor layer 21D, and the gate electrode 22 is formed on the insulating film 61. In the formation of the source electrode 30S, the drain electrode 30D, and the gate electrode 22, Ni layers and Au layers are grown by vapor deposition using a growth mask, and then the growth mask is removed.

Subsequently, the processes from the formation of the insulating film 62 are performed in the same procedure as that of the first example (see FIG. 11 to FIG. 14).

As described above, the semiconductor device 100 according to the embodiment can be manufactured.

The configuration of the semiconductor layer 12 is not particularly limited. For example, the electron supply layer may be provided above the electron transit layer, or the electron transit layer may be provided above the electron supply layer.

Although the embodiments have been described in detail, the present invention is not limited to the specific embodiments, and various modifications and changes can be made within the scope described in the claims.

What is claimed is:

1. A semiconductor device comprising:
a substrate having a first surface and a second surface opposite to the first surface;
a first nitride semiconductor layer having a third surface that is in contact with the second surface and a fourth surface opposite to the third surface, a recess being formed in the fourth surface;
a second nitride semiconductor layer provided in the recess; and
a first metal layer provided on the second nitride semiconductor layer,
wherein a through-hole is formed in the substrate, the first nitride semiconductor layer, and the second nitride semiconductor layer, the through-hole penetrating the substrate, the first nitride semiconductor layer, and the second nitride semiconductor layer and exposing the first metal layer, and
wherein the semiconductor device further comprises a second metal layer that is in contact with the first metal layer and that covers the first surface and an inner wall surface of the through-hole, and
wherein the second nitride semiconductor layer contains impurity atoms at a concentration of 1.0×10¹⁸ cm⁻³ or greater.

2. The semiconductor device as claimed in claim 1, wherein the second nitride semiconductor layer is a gallium nitride layer.

3. The semiconductor device as claimed in claim 1,
wherein the first metal layer includes a nickel layer that is in contact with the second nitride semiconductor layer and is exposed in the through-hole, and
wherein the second metal layer includes a gold layer that is in contact with the nickel layer.

4. The semiconductor device as claimed in claim 1, wherein a Fermi level is higher than energy at a lower end of a conduction band in the second nitride semiconductor layer.

5. The semiconductor device as claimed in claim 1, wherein a carrier density in the second nitride semiconductor layer is higher than a carrier density in the first nitride semiconductor layer.

6. A method of manufacturing a semiconductor device, comprising:
forming a first nitride semiconductor layer on a substrate having a first surface and a second surface opposite to the first surface, the first nitride semiconductor layer having a third surface that is in contact with the second surface and a fourth surface opposite to the third surface;
forming a recess in the fourth surface;
forming a second nitride semiconductor layer in the recess;
forming a first metal layer on the second nitride semiconductor layer;
forming a through-hole in the substrate, the first nitride semiconductor layer, and the second nitride semiconductor layer, the through-hole penetrating the substrate, the first nitride semiconductor layer, and the second nitride semiconductor layer and exposing the first metal layer; and
forming a second metal layer that is in contact with the first metal layer and that covers the first surface and an inner wall surface of the through-hole,
wherein the second nitride semiconductor layer contains impurity atoms at a concentration of 1.0×10¹⁸ cm⁻³ or greater.
